(19) United States
(12) Patent Application Publication
(10) Pub. No.: US 2003/0039094 A1
(43) Pub. Date: Feb. 27, 2003

(54) Closure for equipment case having an integrated display

(76) Inventors: Scott A. Sarkinen, Mounds View, MN (US); Scott A. Davidson, Savage, MN (US); Joseph A. Halfen, Woodbury, MN (US)

Correspondence Address: Kagan Binder, PLLC, Suite 200, 221 Main Street North, Stillwater, MN, 55082-5021, US

(21) Appl. No.: 09/935,293

(22) Filed: Aug. 22, 2001

(51) Int. Cl. H05K 7/00

(52) U.S. Cl. 361/681

(57) ABSTRACT

A pivotable arm assembly functions to demount a door on an electronics assembly and position a display. Preferably, an electronics assembly has a removable door. The removable door has an integral display device for communicating with equipment within the electronics assembly. The door is attached to the electronics assembly by a pivotable arm. In one embodiment, the door, including the display device, may be positioned in a variety of locations with respect to the equipment within the electronics assembly. Thus, in accordance with one specific aspect of the present invention, a display device and the equipment that it communicates with may be simultaneously viewed and accessed.

### TECHNICAL FIELD

The present invention relates to a positionable door for electronics equipment, such as is commonly used in the telecommunications industry. More particularly, this invention pertains to a positionable door for communications equipment having an integrated display device screen that provides point-of-use access to the display device.

### BACKGROUND OF THE INVENTION

As the telecommunications industry has grown, the need to provide cost effective and easy to use racks for the mounting of equipment has also grown. Given the significant space usually required by such equipment, it has become increasingly desirable to mount and organize the equipment as efficiently as possible. Generally, this is done by mininizing the footprint of the rack and by carefully choosing equipment placement within the rack. Additionally, because equipment of this type is frequently expanded and serviced, it is desirable to allow easy access for expansion, modification, and service in general.

It is well-known to provide equipment racks for supporting various types of electronic components for protection of the components, provision of easy access for repair and modification of the components, and organization of wiring and cabling. Racks of this type are frequently used with telecommunications equipment and are particularly well suited for components associated with networks of such equipment. These racks have upright supports with spaced openings. The supports are separated by standard distances depending on whether it is a data rack (19 inches) or a telecommunication rack (23 inches). One such standard, specifically the NEBS (Network Equipment Builders System) standard, utilizes a 19 inch spacing and is commonly used by such communication service providers. These racks may have doors or covers that are provided for protecting equipment mounted within the racks. Where doors are utilized, the doors are typically mounted on hinges and are openable thereby. Covers are generally secured in place using fasteners of some type. That is, covers are usually screwed on or held in place using releasable fasteners, such as latches or clamps and the like.

Typically, telecommunications equipment requires some type of monitoring. The equipment needs to be capable of communicating with technicians so that its operation can be monitored and it can be appropriately serviced. This may include, maintenance, software revision, and diagnostic functions. Occasionally, a technician uses a keyboard and a display to interface with the equipment because the equipment itself does not provide its own independent interface. In order to establish an interface, a technician may attach a keyboard and display into the appropriate interface for the selected equipment thereby creating terminal access. Normally, the monitoring keyboard and display are in a remote location with respect to the actual equipment to be monitored.

Telecommunications systems are typically high reliability systems and need to be continuously monitored. It is common for dedicated rack-mounted monitors and keyboards to be used in these environments. These systems may house monitors within the standard rack. That is, the dedicated rack-mounted monitor is housed in the same rack as the equipment that it monitors. The loss of valuable rack space therefore represents a serious defect. Moreover, this defect is magnified in environments where the monitors are frequently idle and used only during system failures.

Because of the need for efficient space usage, there is usually little space available for storing computer equipment and related monitoring devices. It is not uncommon for the available rack space to be extremely limited and in many cases non-existent. Although there is very little space available for rack-mounted monitors, the monitors are necessary for performing maintenance, software revision, and diagnostic functions. Because space in the rack is typically at a premium, and inefficiently used rack space often equates to lost revenue, it is important that the monitoring equipment occupy as little space as possible.

As another option, a cart-mounted keyboard and monitor may be used. The cart-mounted keyboard and monitor is stored until needed. When monitoring is necessary, a technician typically wheels the monitor cart to the rack requiring monitoring. The technician then cables and connects the monitor and keyboard interfaces to the equipment which requires monitoring. The cart-mounted monitoring solution has the one advantage of not occupying valuable rack space. However, this solution may be less efficient because the cart must be transported from rack to rack and because the keyboard and display interfaces must be cabled and re-cabled to the rack. The requirement of re-cabling and re-connection is time-consuming, inefficient and sometimes costly if the technician makes a mistake.

### SUMMARY OF THE PRESENT INVENTION

The present invention overcomes the deficiencies and shortcomings of the prior art by providing a movable door for an equipment case that has an integrated display device. Such a door provides for positioning the display device such that simultaneous viewing of the display device and equipment to which it communicates therewith is possible.

In one embodiment of the present invention such advantages are achieved by using an electronic equipment support assembly that has an enclosure with spaced sidewalls. The equipment support assembly further includes a support structure operatively connecting the sidewalls. The sidewalls and the support structure further provide support for positioning electronic components and equipment within the enclosure. Also, a door mounted on a movable arm that has an electronic display device including a viewable screen mounted thereon, is utilized. The electronic display device preferably has an electrical connection for communicating with electronic component within the equipment assembly.

Preferably, the display device is a touch screen device so that an operator can interact with equipment supported within the enclosure Preferably, the display device is integrated within the door. Preferably, the screen may be viewed when the door is either opened or closed. The door may be mounted on a pivot arm device that may have multiple sections so that the door can move between open and closed positions. Preferably, when the door is in an open position the door may further swing about its connection to the arm and thereby allow viewing from multiple locations. Further, cables may pass from the display to equipment within the enclosure by passing through the inside of the arm or by being attached to the arm.

These and other features and advantages of the present invention will be apparent in the following detailed description of the preferred embodiments when read in conjunction with the accompanying drawings, in which like reference numerals are used to identify the same or similar parts in the several views.

### BRIEF DESCRIPTION OF THE DRAWINGS

The accompanying drawings, which are incorporated in and constitute a part of this specification, illustrate several aspects of the invention and together with the description of the preferred embodiments, serve to explain the principles of the invention. A brief description of the drawings is as follows:

FIG. 1 is a perspective view of a rack-mountable electronics assembly having an enclosure with a cover plate, a door, and a display device mounted within the door, and in particular showing the electronics assembly mounted on a set of rails and containing a cable management system in accordance with the present invention;

FIG. 2 is a perspective view of the rack-mountable electronics assembly of FIG. 1 showing the door in an opened position and pulled away from the electronics assembly on a pivotable arm, and further illustrating the cable management system mounted within the enclosure of the rack-mountable electronics assembly;

FIG. 3 is a perspective view of the rack-mountable electronics assembly of FIGS. 1 and 2 showing the door in an opened position and pulled away from the electronics assembly but rotated toward the electronics assembly so as to be able to view the display device and components within the electronics assembly simultaneously, and further showing the cover plate of the electronics assembly removed to show the cable management system;

FIG. 4 is a rear perspective view of the rack-mountable electronics assembly of FIG. 1 showing rear mounted electronics components and a cooling fan, and in particular showing a side opening and rear opening for introducing cabling into the electronics enclosure;

FIG. 5 is an exploded perspective view of the door of the electronics assembly of FIGS. 1-4 showing in particular the display device;

FIG. 6 is a left side view of the door in the position illustrated in FIG. 3 showing in particular the pivotable arm;

FIG. 7 is a top view of the door in the position illustrated in FIG. 3; and

FIG. 8 is a front view of the door in the position illustrated in FIG. 3.

### DETAILED DESCRIPTION OF THE PREFERRED EMBODIMENTS

The embodiments of the present invention described below are not intended to be exhaustive or to limit the invention to the precise forms disclosed in the following detailed description. Rather, the embodiments are chosen and described so that others skilled in the art may appreciate and understand the principles and practices of the present invention.

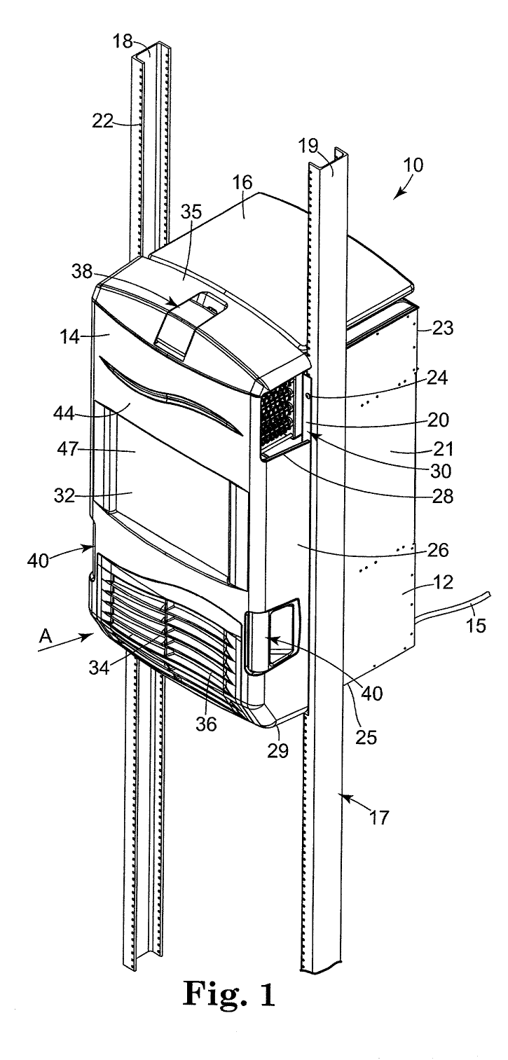

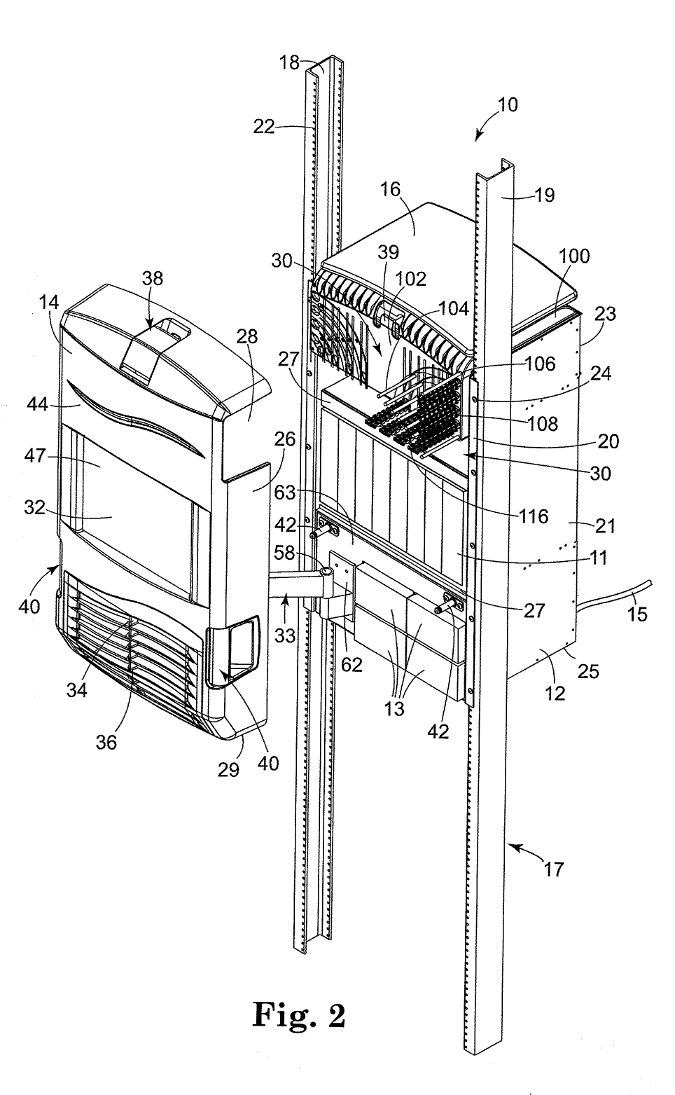

Illustrated in FIGS. 1 and 2 is a rack-mountable electronics assembly 10 in accordance with an embodiment of the present invention. The electronics assembly 10 may, for example, be a signal processing unit for use in the telecommunications industry. The electronics assembly 10 may include signal processing equipment 11 for example, line cards, routers, switches, and the like as well as other modules 13, such as may be one or more power supplies, cooling modules, and the like. The electronics assembly 10 may further include a main power cable 15 for delivering outside power to the electronics assembly 10. The main power cable 15 is preferably introduced through a back wall 23 of the electronics assembly 10 however; the main power cable 15 may be introduced through any wall of the electronics assembly 10 such that the functional aspects of the present invention are realized. The electronics assembly 10 preferably includes a cable management system 30 for handling cables associated with the signal processing equipment and for handling any other cabling within the electronics assembly 10. The cable management system 30, as illustrated in FIG. 2, is the subject of commonly owned co-pending U.S. patent application Ser. No. ______,” entitled “Cable Management System and Apparatus”, filed on even date herewith, and the entire disclosure of which is fully incorporated herein by reference.

As illustrated in FIGS. 1 and 2, the electronics assembly 10 generally includes an enclosure 12, a door 14, a cover plate 16, and the cable management system 30. Specific details of the enclosure 12, door 14, cover plate 16, and cable management system 30 are set out below. Preferably, the electronics assembly 10 is mounted to and supported by a support structure 17 having a first vertically mounted rail 18. As illustrated in FIGS. 1 and 2, the rail 18 may be generally U-shaped in cross-section and preferably has fastener holes 22 spaced evenly apart along the rail 18 at a predetermined distance. Preferably the support structure 17 is provided having a second rail 19 spaced at an industry standard distance from the first rail 18. Preferably the first rail 18 and the second rail 19 are substantially parallel. In a preferred embodiment, the first rail 18 and the second rail 19 are spaced at an industry standard distance of 19 inches such as the NEBS (Network Equipment Builders System) standard. Preferably, such support structures 17 are mounted to additional supporting frame structures (not shown) and extend from floor to ceiling within buildings. Likewise, other indoor applications may include mounting the electronics assembly 10 to walls, poles, or other structures. It is contemplated that the support structure 17 may be utilized such that access to all sides of the electronics assembly 10 is available.

Preferably, a plurality of support structures 17 may be provided such that electronics assemblies 10 are arranged in a side by side configuration thereby efficiently utilizing space. Further, it is contemplated that, multiple electronics assemblies 10 may be mounted on the same support structure 17 thus creating a stacked arrangement of electronics assemblies 10. As such, a side by side and/or stacked arrangement of electronics assemblies 10 may be accomplished thereby satisfying any applicable space utilization requirements.

It is noted that similar electronics assemblies may be utilized in outdoor applications, such as electronics assemblies mounted onto exterior walls of buildings and utility poles and other such structures. As such, the functional aspects of the cable management system of the present invention would not be precluded for such outdoor applications.

In a preferred embodiment, the enclosure 12 has sidewalls 21, the back wall 23, and a bottom wall 25. The enclosure 12 may be formed by any known or developed technique. For example, sidewalls 21, back wall 23, and bottom wall 25 may be formed from sheet material and as individual components and joined together by welding. Alternatively, sidewalls 21, back wall 23, and bottom wall 25, maybe formed from sheet material and as individual components and having flanges allowing for fastening together with rivets, screws, or the like, as is conventionally known. As another alternative, the enclosure 12 may be formed by bending a single sheet of material or multiple sheets of material thereby forming the sidewalls 21, back wall 23, and bottom wall 25.

The enclosure 12 may include frame structures for providing structural strength, dividing the enclosure 12 into multiple zones, or for providing mounting points for internal components of the enclosure 12. In FIG. 2, exemplary horizontal frame structures 27 are illustrated. The frame structures 27 may be mounted within the enclosure 12 to extend between sidewalls 21 (as illustrated in FIG. 2) or may be mounted horizontally (not shown) to extend from the bottom wall 25 or in any combination of horizontal and vertical structure such that the functional aspects of the present invention are realized. For example, the frame structures 27 may be formed as a single frame unit having the sidewalls 21, back wall 23, and bottom wall 25 attached thereto by any conventional means. As illustrated in FIG. 2, frame structures 27 dividing enclosure 12 into three zones. That is, a zone for the cable management system 30, the signal processing equipment 11, and the other modules 13 is provided. It is noted that the enclosure 12 may be divided by any number of frame structures 27 to create any number of zones desired.

Preferably, the enclosure 12 has a flange 20 extending outward from each sidewall 21 of the enclosure 12 for mounting the electronics assembly 10 to the support structure 17. That is, the flange 20 of the electronics assembly 10 is attached to rail 18 on one side and to rail 19 on the opposite side. As illustrated in FIG. 2 the flange 20 is preferably L-shaped in cross-section and includes mounting holes (not shown) for attaching the flange 20 to rail 18 and rail 19 via tapped holes 22 thereby supporting the electronics assembly 10 on the rail 18 and rail 19. It is known that the flange 20 may be any known or developed structure capable of attaching the electronics assembly 10 to the rail 18 and rail 19. That is, the flange 20 is not required to be an integral part of the enclosure 12. The flange 20 may be a separate structure for example, a bracket. It is noted that any suitable fasteners 24 may be used to secure the electronics assembly 10 to the rail 18 and rail 19. In an alternate embodiment, the electronics assembly 10 may be implemented as a tabletop electronics assembly. That is, any such supporting rail, such as rail 18 and rail 19, may be omitted. It is noted that the manner of supporting the electronics assembly 10 does not form a specific part of the present invention and may comprise any conventional or developed structure.

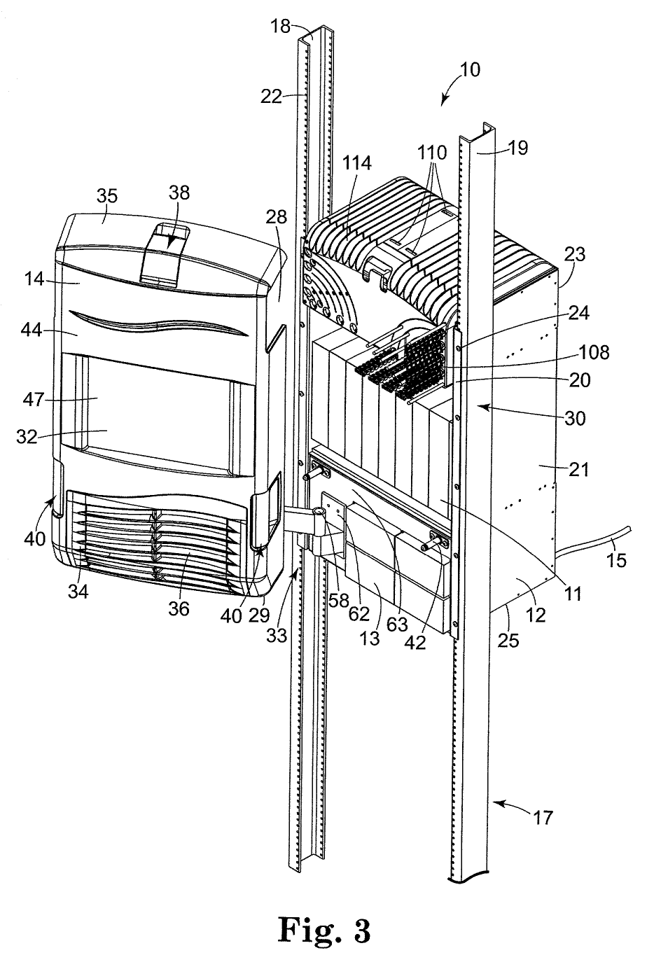

In a preferred embodiment, the electronics assembly 10 includes the cable management system 30 mounted within the enclosure 12. Preferably, as illustrated in FIG. 2, the cable management system 30 includes a cable support tray 100, a cable guide plate 102, a plurality of cable support pins 104, a plurality of cable guide pins 106, and a plurality of horizontal and vertical cable capture trees 108 and 116 respectively. The cable management system 30 is preferably supported within the enclosure 12 using frame structure 27 as described above. That is, the cable guide plate may be mounted to frame structure 27 or any other frame structure within the enclosure 12 to extend between sidewalls 21 at the top of the enclosure 12. Preferably the cable support tray 100 is horizontally positioned and mounts to the cable guide plate 102 that is preferably vertically positioned. Preferably, the cover plate 16 mounts to the cable support tray 100 by using mounting features 110 illustrated in FIG. 3.

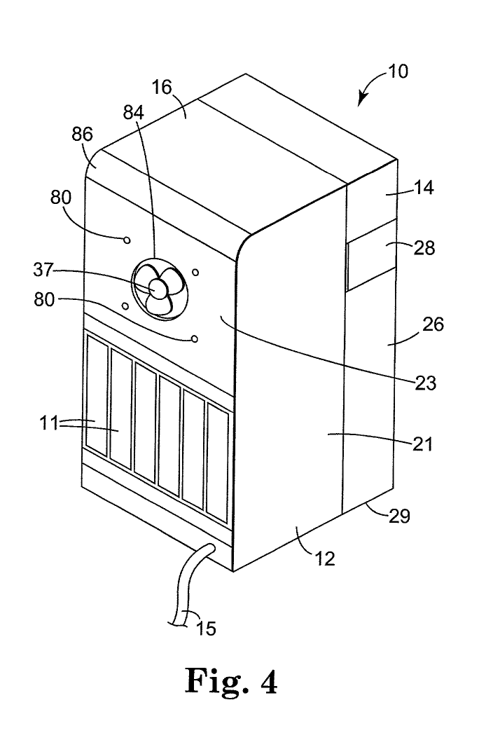

In the preferred embodiment, cables may enter the enclosure 12 through openings 28 in the side panels 26 of door 14 or through a rear opening 86 in the rear panel 23 (as seen in FIG. 4) in any combination thereof. Cables entering through the rear opening 86 are preferably supported and guided by the channels 112 in the cable support tray 100. Cables that are supported by the cable support tray 100 may then pass over the cable guide plate 102 and be directed downward by saddles 114 to the cable capture trees 108. The cable capture trees 108 include openings (not visible) for holding the cables such that they remain organized and neatly arranged within the cable management system 30. Cables entering through the side openings 28 pass through the openings (not visible) of the vertical cable capture trees 108 and then pass over the cable support pins 104 and are directed to the horizontal cable capture trees 116 thereby been directed downward to the signal processing equipment 11 and other modules 13.

As mentioned above, the electronics assembly 10 in accordance with the present invention includes a swingable door 14 for protecting equipment within the electronics assembly 10. That is, cables attached to signal processing equipment 11 are protected from damage and from accidentally being disconnected by being contacted. Preferably, the door 14 has a front panel 44, opposing sidewalls 26, and a bottom panel 29. In a preferred embodiment, the door 14 is formed as a single molded structure. It is contemplated that the door may be formed from individual structures. For example, the front panel 44, opposing sidewalls 26, and the bottom panel 29 may be formed as individual structures and joined together by any conventional or developed means such that the functional aspects of the present invention are realized.

Preferably, the door 14 has at least one opening 28 in each sidewall 26 for passing cables from outside the electronics assembly 10 to inside the electronics assembly 10. Cables pass through the opening 28 and are arranged by the cable management system 30 within the enclosure 12. As illustrated in FIGS. 1 and 2, the opening 28 may be generally square. Further, the opening 28 may be in one sidewall 26 of the door 14 or may be in both opposing sidewalls 26 of the door 14. The opening 28 is preferably positioned in the sidewall 26 of the door 14 such that it is aligned with the cable management system 30. Preferably, the opening 28 is open at an end such that the door 14 can be opened without disturbing cables passing through the opening 28 and secured by the cable management system 30. The opening 28 may be of any shape as long as the functional aspects of the present invention are realized. That is, the shape of the opening 28 is not critical as long as a predetermined number of cables can pass through it and remain sufficiently undisturbed when the door 14 is opened or removed. It is preferable that cables can pass through the opening 28 and be supported by the cable management system 30 such that they remain untangled and organized. Preferably the opening 28 has a rectangular shape however, the opening 28 may have a circular shape or any other shape that allows cables to pass through the door 14. It is contemplated that the opening 28 may additionally have a structure or mechanism utilized for strain relief of the cables passing through the opening 28. For example, the opening 28 may have a clamp type structure (not shown) for strain relief of the cables such that a portion of the clamp could be removed in order to open the door 14 without disturbing the cables.

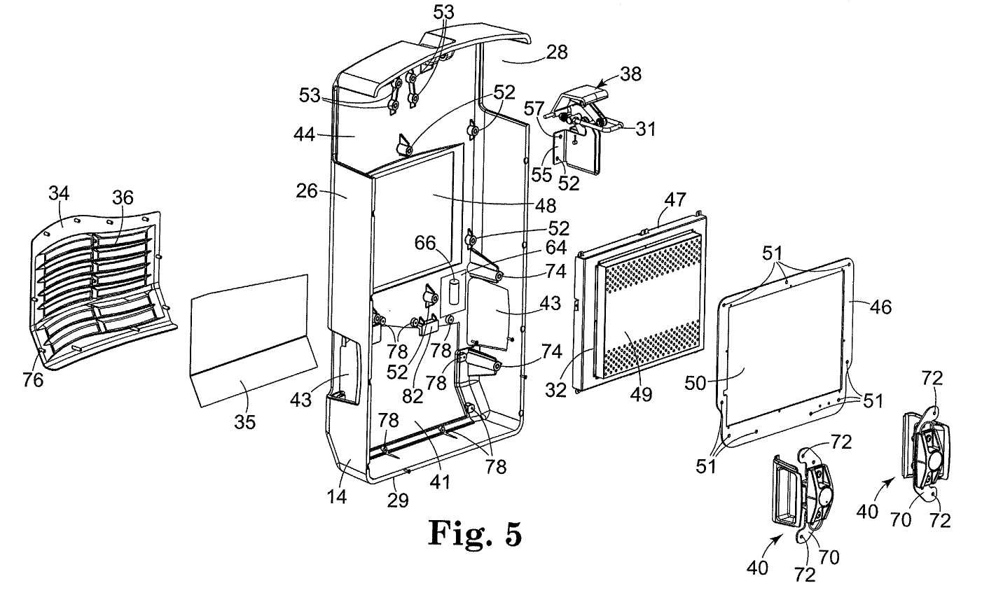

As shown in FIGS. 1 and 2, the door 14 preferably includes a latch 38 positioned centrally at the top of the door 14 for securing to latch tab 39 and thereby securing the door 14 to the enclosure 12. Referring to FIG. 5, the latch 38 preferably includes a bail 31 that is pivotable to engage latch tab 39 and which bail 31 is tightenable by a mechanism as conventionally known. The latch 38 preferably includes a mounting flange 55 having mounting holes 57 for securing to mounting holes 53 on the door 14. It is noted that the latch 38 may be replaced with any conventional or developed structure such that the functional aspects of the present invention are realized. That is, any means of securing the door 14 to the enclosure 12 such as, releasable fasteners, clamps, and any other such latching mechanism or the like may be used.

Preferably the latch tab 39 is independent of the cover plate 16 so that the cover plate 16 may be removed while the door 14 is secured to the enclosure 12. The bail 31 of the latch 38 may pass over the latch tab 39 such that the latch 38 can control the bail 31 with the latch tab 39 to hold the door 14 in its closed position. Preferably the latch tab 39 is a feature of the cable management system 30, specifically, the latch tab 39 is part of the cable guide plate 102. However, the latch tab 39 may be a feature of the cover plate 16 or may be a feature of the enclosure 12 or any other component within the enclosure 12 such that the functional aspects of the present invention are accomplished.

Also shown in FIGS. 1 and 2, the door 14 preferably includes a releasable handle 40 as part of each sidewall 26. As can be seen in FIG. 5 the door 14 preferably includes an opening 43 in each sidewall 26 for accommodating the releasable handle 40. Preferably the releasable handle has a mounting flange 70 having mounting holes 72. As is also shown in FIG. 5 the door 14 includes mounting hubs 74 for attaching the releasable handle 40 by using mounting holes 72 in the mounting flange 70.

Referring to FIGS. 1 and 2 the enclosure includes pins 42 attached to frame structure 63 and positioned to engage with the releasable handle 40. Each releasable handle 40 engages pin 42 and secures the door 14 to the enclosure 12. Preferably, the pin 42 and releasable handle 40 combination utilizes a locking mechanism (not shown) to make the closure. That is, pin 42 has a detent (not shown) capable of receiving a spring-loaded lock (not shown) that is part of the releasable handle 40.

The latch 38 and each releasable handle 40 secure the door 14 to the enclosure 12. In demounting the door 14 from the enclosure 12, first, the latch 38 is opened and thereby releasing the bail 31 of the latch 38 from the latch tab 39. Next, using both hands, each releasable handle 40 is disengaged simultaneously thereby fully releasing the door 14 from the enclosure 12. It is known that any conventional or future developed latching arrangement may be used to secure the door 14 to the enclosure 12. That is, the latch 38 and latch tab 39 as well as the releasable handle 40 and pin 42 may be replaced by any conventional or future developed mechanism or means such that the functional aspects of the present invention are realized.

Preferably, as illustrated in FIG. 1, the door 14 also includes a ventilation grill 34. The ventilation grill 34 includes air intake apertures 36 for permitting air to flow into the electronics assembly 10 in order to cool the internal electronic components of the electronics assembly 10. The air intake apertures 36 may be any such openings that permit air to enter the enclosure 12 in accordance with the functional aspects of the present invention. As illustrated in FIG. 1 air may generally flow in the direction of arrow A, pass through the air intake apertures 36 and through the opening 41 illustrated in FIG. 5 to enter the enclosure 12. As illustrated FIG. 5, the ventilation grill 34 is preferably formed as a single structure. It is contemplated that the ventilation grill 34 may be formed as an integral part of the door 14. That is, the door 14 and ventilation grill 34 may be formed as a single structure. It is further contemplated that the ventilation grill 34 may be formed as a plurality of structures that are either attached to the door 14 or formed as part of a single structure door 14. The ventilation grill 34 is the subject of commonly owned co-pending U.S. Design patent application Ser. No. ______,” entitled Ventilation Grill, filed on even date herewith, and the entire disclosure of which is fully incorporated herein by reference.

Preferably, the ventilation grill 34 includes mounting hubs 76 located around at least part of the perimeter of the ventilation grill 34. Preferably, mounting hubs 76 pass through mounting holes 78 of the door 14 thereby securing the ventilation grill 34 to the door 14. In a preferred embodiment, the mounting hubs 76 are frictionally secured within the mounting holes 78 of the door 14 thereby allowing the ventilation grill 34 to be releasable. It is contemplated that the ventilation grill 34 may be secured to the door 14 using any conventional fasteners or the like. The ventilation grill 34 may be secured to the door 14 using screws, rivets, or the like.

The ventilation grill 34 may include an air filter 35 as illustrated in FIG. 5. Such an air filter 35 may be used to prevent dust and other harmful contaminants from entering the electronics assembly 10. Preferably the air filter 35 is sandwiched between the ventilation grill 34 and the door 14. Preferably, the door 14 includes a flange 82. In a preferred embodiment the air filter 35 is captured between the ventilation grill 34 and the flange 82. It is contemplated that the air filter 35 may be any known or developed filtration media, multiple layers, or formed media with or without additional filter frames.

As shown in FIG. 4, the enclosure 12 may include at least one fan 37 for drawing air into the electronics assembly 10 for providing cooling to the components within the electronics assembly 10. Preferably, air flows in the direction of arrow A into the air intake apertures 36 and through the electronics assembly 10 under the drawing force of the fan 37. Preferably, the fan 37 is mounted to the inside of the rear panel 23 of the enclosure 12 by using mounting holes 80 and any conventional fasteners (not shown). In a preferred embodiment the rear panel 23 of the enclosure 12 includes at least one air passage 84 for permitting air to exit the enclosure 12 under the drawing force of the fan 37. Preferably, the fan 37 is positioned over the air passage 84. The number and type of fans 37 utilized is dependent upon the particular components within the electronics assembly 10. That is, certain components require a greater degree of cooling and as such would require greater airflow through the electronics assembly 10.

In a preferred embodiment, the door 14 includes at least one integrated display device 32. By a display device, it is meant any electronic device known or developed that can provide visual communication based upon one or more of the electronic components to which is attached. Preferably, the display device 32 is an input capable display device. That is, it is preferably an interface to permit two-way communication with electronic components to which it is attached. For example, the input capable display device may be connected to the signal processing equipment 11 to accomplish setup or diagnostics etc., or may be merely a warning device, preferably both, as described in greater detail below.

Preferably, the display device 32 is a touch screen display capable of providing two-way communication with components to which it is connected. The display device functions as both a display device and input device such that a technician may input commands and the like to communicate with attached equipment. It is contemplated that any input capable display device may be used. That is, commands are entered through the display device by touching the screen with a finger or stylus or through the use of a keyboard or other remote means for communicating therewith, which keyboard can be also directly mounted to the door 14 or plugged into the display and may further utilize wireless communication technology either known or developed.

The display device 32 is preferably a flat panel input capable display device having a low profile for efficient space utilization such as a liquid crystal display, light emitting diode display, field emission display, plasma display, or the like. The display device 32 may be any such size and shape facilitating such use such that the functional aspects of the present invention are realized. The display device 32 may be a black and white display or may be a color display. Preferably the display device 32 is a commercially available touch screen display model NIS-TNC-1503-215 as commercially available from ELO TouchSystems of Fremont, Calif.

Referring to FIG. 5, an exploded view of the door 14 is illustrated. Preferably, the door 14 has an opening 48 positioned centrally in the front panel 44 for accommodating the display device 32. The opening 48 allows the display device to be mounted on to the backside of the front panel 44 such that a clean appearance results. As described below, it is contemplated that the display device 32 may be mounted directly onto the front panel 44 of the door 14. That is, the opening 48 in the door 14 may be omitted.

The display device includes a viewing side 47 and may have a raised portion 49 for housing screen driving components, as conventionally known. In the preferred embodiment, the display device 32 is positioned within the opening 48 so that the viewing side 47 is viewable from the outside of the electronics assembly 10. That is, the display device is viewable when the door 14 is closed. In an alternate embodiment, the display device may be positioned such that the viewing side 47 faces into the enclosure 12. That is the display device 32 may be positioned inside the door 14 (and not viewable when the door 14 is closed) so as to be viewable when the door 14 is open and to utilize the advantages of the pivotable arm assembly 33 described below.

As illustrated in FIG. 5, the display device 32 can be secured to the door 14 by using a mounting frame 46. The mounting frame 46 includes an opening 50 and mounting holes 51. The door 14 has mounting hubs 52 that are used for attaching the mounting frame 46 to the rear side of the front panel 44. The raised portion 49 of the display device 47 fits within the opening 50 of the frame 46 and the mounting holes 51 of the frame 46 are used to attach the frame to the mounting hubs 52 of the door 14 thereby securing the display device 32 to the door 14. That is, the display device 32 is sandwiched between the mounting frame 46 and the rear side of the front panel 44 of the door 14 around the opening 48. Any suitable fasteners (not shown) may be used for attaching the frame 46 to the door 14.

Any means for positioning the display device 32 on or within the door 14 such that the functional aspects of the present invention are realized may be utilized.

For example, as discussed above, the display device 32 may be attached directly onto the door 14, to either the front or rear side of the front panel 44 without providing any opening through it. Further, it is contemplated that the display device 32 may be mounted on or within the door 14 by a hinge, arm, or any other such mechanism to position and provide maneuverability to the display device such that its viewability with respect to electronic components within the electronics assembly 10 can be optimized.

The display device 32 is preferably a low-profile display device, as described above, so as to occupy a minimal amount of space within the door 14. Typically, the display device 32 is utilized for interfacing with the signal processing equipment 11. Preferably, the display device 32 is connected to the signal processing equipment 11 with any number of wires or cables (not shown) having appropriate connections for the display device and the signal processing equipment as known or developed. As discussed below, these wires are routed through the pivotable arm assembly 33 so that they may interface with the signal processing equipment 11. It is contemplated that the display device 32 may communicate with the signal processing equipment 11 by any known or developed signal-based communications technique. That is, any hard wire or wireless type of signal-based communication may be used such as, conventional metal wire, fiber optic wire, infrared, radio frequency, or other electromagnetic technology or the like.

In a preferred embodiment, the door 14 is connected to the enclosure 12 using a pivotable arm assembly 33 as illustrated in FIGS. 2 and 3, to permit the door 14 to be opened once latches 38 and 40 are unlatched and to permit the door 14 to be easily moved in any number of positions to facilitate use of the display device 32. In FIG. 2 the door 14 is illustrated in an open position and pulled away from the closed position illustrated in FIG. 1. In this position it would be difficult for a technician to view both the display device 32 and the signal processing equipment 11 as well as the other modules 13 that are within the enclosure 12 of the electronics assembly 10. In this position however, greater access to the entire electronics assembly 10 is provided for example, easier access to rails 18 and 19 may be provided. Also, the entire electronics assembly 10 may be mounted inside another enclosure because of the versatility of the door 14. In FIG. 3 the door 14 is illustrated in an open position pulled away from the enclosure 12. However, unlike the position illustrated in FIG. 2, the door 14 is also rotated towards the enclosure 12 in FIG. 3.

Is contemplated that the door 14 may be connected to the enclosure 12 using any conventional hinge type structure. That is, the door 14, having the display device 32, may be connected to the enclosure 12 such that it is hinged at a side of the enclosure 12 or at the top or bottom of the enclosure 12. The display device 32 may be viewable at the location of the signal processing equipment 11 as well as the other modules 13 that may be within the enclosure 12 of the electronics assembly 10 without the use of additional equipment. That is, a separate display, either remote or mobile, may not be necessary. It is further contemplated that the integrated door 14 and display device 32 may be utilized as a warning indicator when the door 14 is mounted using either the pivotable arm assembly 33 or the conventional hinge type structure described above. It is further contemplated that the display device 32 may be attached to the door 14, as described above, such that the viewing side 47 of the display device 32 faces towards the inside of the enclosure 12. As such, the display device 32 may be viewable simultaneously with the signal processing equipment 11 as well as the other modules 13 that may be within the enclosure 12 of the electronics assembly 10 when the door 14 is opened using the hinge type structure described above.

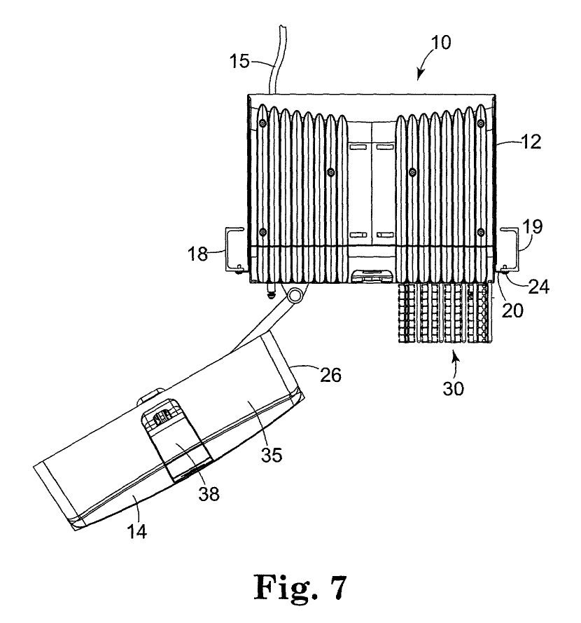

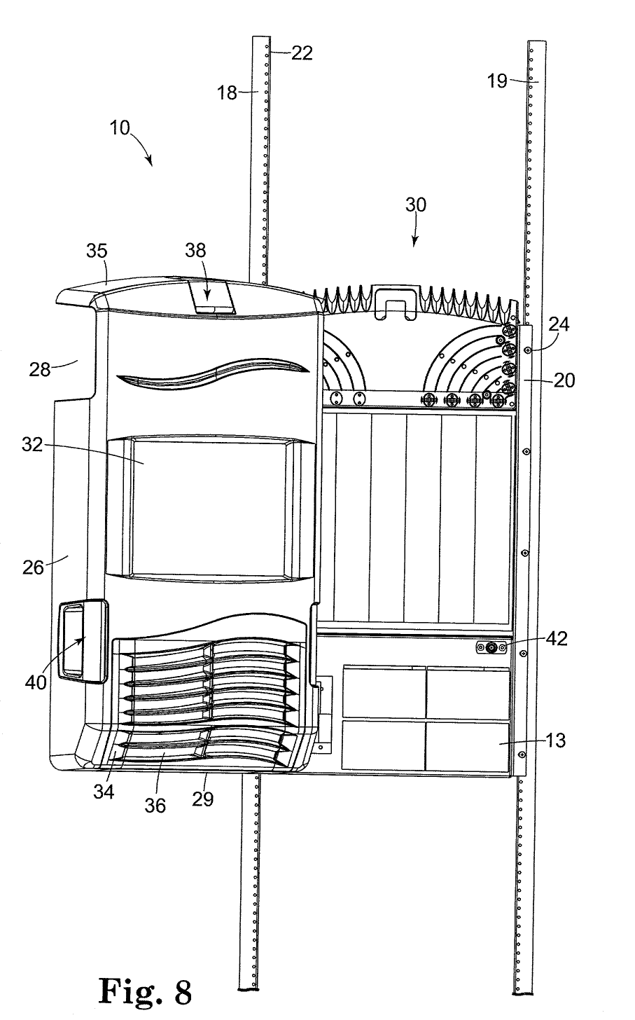

The rotated position of the door 14 shown in FIG. 3 is also illustrated as a top view in FIG. 7 and as a front view in FIG. 8. In the rotated position of FIGS. 3, and 78 the display device 32 of the door 14 and the equipment within the enclosure, i.e., the signal processing equipment 11, are simultaneously viewable. That is, the signal processing equipment 11 and the other modules 13 may be easily seen at the same time as the display device 32. Further, the door 14 may be positioned in a wide range of locations for viewing the display device 32. A technician working behind or to the side of the electronics assembly 10 can easily place the door 14 in a position to readily view the display device 32.

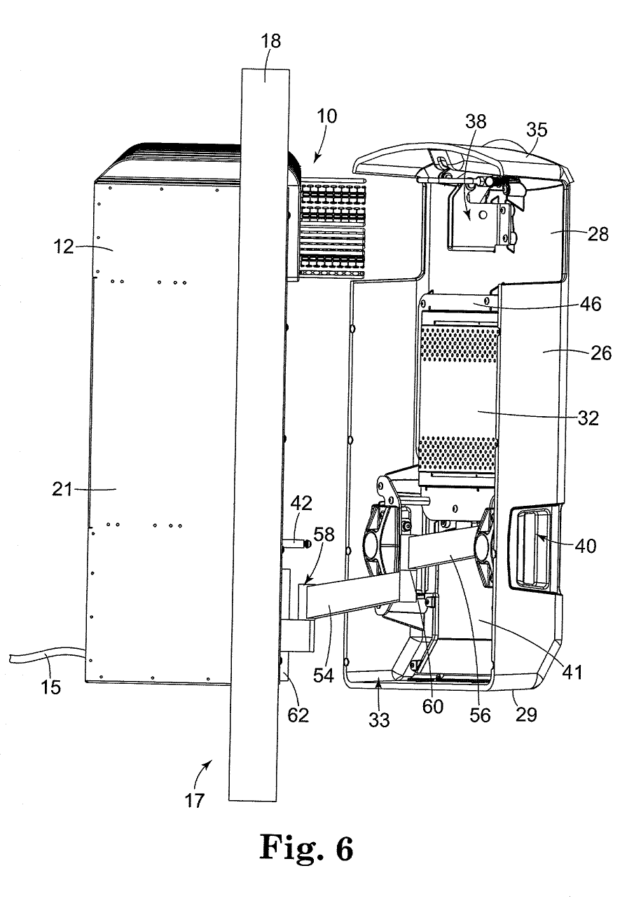

In FIG. 6, the pivotable arm assembly 33 is illustrated. Preferably the pivotable arm assembly 33 includes a first arm 54, a second arm 56, a first mounting plate 62, and a second mounting plate 64 (see FIG. 5). The first mounting plate 62 is preferably connected to a frame structure 63 (see FIG. 2) provided as a structural component of the enclosure 12. An end of the first arm 54 is pivotally connected to the mounting plate 62 at a first pivot point 58. An end of the second arm 56 is connected to the opposite end of the first arm 54 at a second pivot point 60. The second mounting plate 64 is mounted to the inside of the door 14 and is illustrated in FIG. 5. The opposite end of the second arm 54 is further connected to the second mounting plate 64 at a third pivot point 66 as can be seen in FIG. 5.

It is noted that any pivotable arm assembly may be used and appropriately connected such that the functional aspects of the present invention are realized. That is, any pivotable arm assembly that allows the door 14, including the display device 32, to be demounted from the enclosure 12 and positioned such that the display device 32 and equipment within the enclosure 12 are simultaneously viewable may be used.

The pivotable arm assembly 33 preferably includes means for passing wires from the display device 32 to other electronic equipment either within the enclosure 12 or remotely located. Such means may include attaching wires to the outside of the pivotable arm assembly 33 such that the door 14 may be rotated through a variety of positions without pinching or entangling the wires. Wires may be attached to the pivotable arm assembly by any conventional means. For example, wires may be attached by using known wire-ties or clips or by using adhesives. The wire management may be integrated with the arm 33. Alternatively, wires may pass through the interior of the first arm 54 and through the interior of the second arm 56 such that cables operatively pass from the display device 33 to signal processing equipment 11, other modules 13, or to any other equipment such as power supplies, driving devices, or the like.

Preferably the pivotable arm assembly 33 includes means for holding the door 14 at a predetermined position. Such means may be frictional resistance obtained as a result of the weight of the door 14 and arm 33. This is especially useful when using a touch screen type display device as described above. That is, the pivotable arm assembly 33 may includes spring mechanisms, counter weight mechanisms, friction disks, or any such resistance means that provides a force to hold the pivotable arm assembly 33, and thereby the door 14 and display device 32, at a predetermined location. For example, a suitable pivotable arm assembly 33 model 28-110-180 is available from Ergotron of St Paul, Minn.

The present invention is not limited to the above described preferred apparatus. More generally, the invention embraces a pivotable door with an integral display device for use with an electronics assembly. Furthermore, it should be understood that, while particular embodiments of the invention have been discussed, this invention is not limited thereto as modifications may be made by those skilled in the art, particularly in light of the foregoing teachings. Accordingly, the appended claims contemplate coverage of any such modifications as incorporate the essential features of these improvements within the true spirit and scope of the invention.

What is claimed is:

1. An electronic equipment support assembly having an enclosure with at least a pair of spaced sidewalls and support structure operatively connecting the sidewalls, the sidewalls and the support structure further providing support for positioning at least one electronic component within the enclosure, the electronic equipment support assembly further comprising a door movably connected to the enclosure between an open position and a closed position for closing at least a portion of the enclosure, the door having an electronic display device including a viewable screen mounted thereon, and the electronic display device having a signal-based connection for communication with an electronic component when mounted within the enclosure.

2. The electronic equipment support assembly of claim 1, wherein the electronic display is integrated within the door.

3. The electronic equipment support assembly of claim 2, wherein the electronic display is mounted within the door so that the viewable screen can be viewed from outside the enclosure when the door is in its closed position.

4. The electronic equipment support assembly of claim 3, wherein the electronic display further includes an input device so that an operator can interact with an electronic component when supported within the enclosure.

5. The electronic equipment support assembly of claim 4, wherein the electronic display comprises a touch screen to provide viewability and interactivity with an electronic component when supported within the enclosure.

6. The electronic equipment support assembly of claim 5, further including at least one wiring cable that is electrically connected with the touch screen and running from the touch screen as mounted within the door to within the enclosure for providing signal-based communication with an electronic component when supported therein.

7. The electronic equipment support assembly of claim 5, further including a wireless communicator for at least receiving signals from another wireless communicator provided within the enclosure and that is connectible with an electronic component when supported within the enclosure.

8. The electronic equipment support assembly of claim 5, further including a pivot arm having a first end pivotally connected to the door and a second end pivotally connected to the enclosure so that the door can move between opened and closed positions, and so that, in the open position, the pivot arm is extended out of the enclosure and the door can further swing about its pivotal connection with the first end of the arm.

9. The electronic equipment support assembly of claim 8, wherein the pivot arm comprises a plurality of arm elements that are articulated together between the first and second end of the pivot arm.

10. The electronic equipment support assembly of claim 9, further including at least one wiring cable that is electrically connected with the touch screen and running from the touch screen as mounted within the door to within the enclosure for providing signal-based communication with an electronic component when supported therein, and wherein at least a portion of the pivot arm includes a passage for guiding the wiring cable within it.

11. An electronic equipment support assembly having an enclosure comprising a pair of spaced sidewalls and a back wall operatively connecting the sidewalls to create an open enclosure, the sidewalls being further connected with support structure that together provide support for positioning at least one electronic component within an area of the enclosure, the electronic equipment support assembly further comprising a door movably connected to the enclosure between an open position and a closed position for closing the open enclosure, the door having an electronic display device including a viewable screen mounted thereon, and the electronic display device having a signal-based connection for communication with an electronic component when mounted within the enclosure.

12. The electronic equipment support assembly of claim 11, wherein the door further comprises a ventilation grill permitting air to flow through the door when the door is closes for ventilating the enclosure.

13. The electronic equipment support assembly of claim 12, further comprising a cable management system provided within the enclosure for guiding a plurality of cables into the enclosure and to the electronic component support area.

14. The electronic equipment support assembly of claim 13, further in combination with at least one electronic component supported within the electronic component support area of the enclosure, the electronic component being in electrical communication with the electronic display device.

15. The electronic equipment support assembly and electronic component combination of claim 14, wherein the electronic display is integrated within the door.

16. The electronic equipment support assembly and electronic component combination of claim 15, wherein the electronic display is mounted within the door so that the viewable screen can be viewed from outside the enclosure when the door is in its closed position.

17. The electronic equipment support assembly and electronic component combination of claim 16, wherein the electronic display further includes an input device so that an operator can interact with the electronic component supported within the enclosure.

18. The electronic equipment support assembly and electronic component combination of claim 17, wherein the electronic display comprises a touch screen to provide viewability and interactivity with the electronic component supported within the enclosure.

19. The electronic equipment support assembly and electronic component combination of claim 18, further including at least one wiring cable that is electrically connected with the touch screen and running from the touch screen as mounted within the door to within the enclosure for providing communication with the electronic component supported therein.

20. The electronic equipment support assembly and electronic component combination of claim 18, further including a wireless communicator for at least receiving signals from another wireless communicator provided within the enclosure and that is connectible with the electronic component supported within the enclosure.

21. The electronic equipment support assembly and electronic component combination of claim 18, further including a pivot arm having a first end pivotally connected to the door and a second end pivotally connected to the enclosure so that the door can move between opened and closed positions, and so that, in the open position, the pivot arm is extended out of the enclosure and the door can further swing about its pivotal connection with the first end of the arm.

22. The electronic equipment support assembly and electronic component combination of claim 2 1, wherein the pivot arm comprises a plurality of arm elements that are articulated together between the first and second end of the pivot arm.

23. The electronic equipment support assembly and electronic component combination of claim 22, further including at least one wiring cable that is electrically connected with the touch screen and running from the touch screen as mounted within the door to within the enclosure for providing communication with the electronic component supported therein, and wherein at least a portion of the pivot arm includes a passage for guiding the wiring cable within it.
